(19) United States
(12) Patent Application Publication
(10) Pub. No.: US 2025/0036021 A1
(43) Pub. Date: Jan. 30, 2025

(54) EXTREME ULTRAVIOLET LITHOGRAPHY METHOD AND EUV PHOTOMASK

(71) Applicant: TAIWAN SEMICONDUCTOR MANUFACTURING COMPANY LTD., HSINCHU (TW)

(72) Inventors: CHIEN-MIN LEE, HSINCHU COUNTY (TW); YEN-LIANG CHEN, HSINCHU COUNTY (TW); SHY-JAY LIN, HSINCHU (TW); LEE-FENG CHEN, NEW TAIPEI CITY (TW); KUO LUN TAI, HSINCHU CITY (TW)

(21) Appl. No.: 18/360,853

(22) Filed: Jul. 28, 2023

(51) Int. Cl. G03F 1/32; G03F 1/54

(52) U.S. Cl. CPC G03F 1/32; G03F 1/54

(57) ABSTRACT

An attenuated phase-shifting mask (APSM) includes a substrate, a multi-layer structure, a capping layer and an absorber layer. The substrate has a first side and a second side opposite to the first side. The multi-layer structure is disposed over the first side of the substrate. The capping layer is disposed over the multi-layer structure. The absorber layer is disposed over a portion of the capping layer. The absorber layer includes a first material and a second material different from the first material. A thickness of the absorber layer is between approximately 30 nm and approximately 65 nm. A refractive index (n) of the absorber layer is between approximately 0.860 and approximately 0.945. An extinction coefficient (k) of the absorber layer is between approximately 0.070 and approximately 0.015.

### BACKGROUND

The semiconductor industry has experienced rapid growth, due in part to ongoing improvements in integration density of a variety of electronic components (e.g., transistors, diodes, resistors, capacitors, etc.). For the most part, improvements in integration density have resulted from iterative reduction of minimum feature size, which allows more components to be integrated into a given area. This scaling down has introduced increased complexity to the semiconductor manufacturing process.

As one example, photolithography processes may use a photomask (also referred to as a reticle) to optically transfer patterns onto a substrate. The minimum feature size that may be patterned by way of such lithography process is limited by a wavelength of its projected radiation source. In view of such limitation extreme ultraviolet (EUV) radiation sources and lithography processes have been introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of an EUV lithography system according to aspects of the present disclosure.

FIG. 2 is a cross-sectional view of an EUV photomask according to aspects of the present disclosure.

FIGS. 3A to 3C are schematic cross-sectional views of an absorber layer of various embodiments according to aspects of the present disclosure.

FIGS. 4A, 4B, 5A, 5B, 6 and 7 are coordinate diagrams of optical characteristics of absorber layers including refractive indices and extinction coefficients of different materials and thicknesses of the absorber layers.

FIG. 8 is a flowchart of an EUV lithography method according to aspects of the present disclosure.

FIG. 9 is a cross-sectional view of an EUV photomask during an EUV lithography operation according to aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that may exist alone or in other combinations of features; rather, the scope of the disclosure shall be defined by the claims appended hereto.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing. For these benefits to be realized, similar developments in IC processing and manufacturing are needed. For example, it becomes more important to perform lithography processes having greater resolution.

In some embodiments, greater feature resolution and density at higher wafer exposure throughput may be achieved by enhancing image contrast. In some embodiments, normalized image log slope (NILS) is calculated for a feature as a part of a performance index. NILS is a measure of how abruptly light intensity changes. For this reason, NILS is often used in contrast checks, because sharply-defined transitions from dark to light provide precise exposure and well-defined features. Contrast checks that include the NILS-based checks may be used to determine whether a mask feature will create a corresponding feature on a substrate and may also be used to determine whether the substrate feature will be the correct size and/or shape. In some comparative embodiments, at least two approaches are provided to improve image contrast. One is to increase a numerical aperture (NA) of an EUV scanner, and another is to adopt an attenuated phase-shifting mask (APSM) absorber to minimize a mask 3D (M3D) effect, which cannot be minimized by conventional binary absorbers.

In the present disclosure, an absorber layer is provided to an APSM used in EUV lithography. The APSM including the absorber layer may achieve improved image contrast by manipulating or modifying a composition and a thickness of the absorber layer. Accordingly, instead of increasing the NA of the EUV scanner, the image contrast is easily and practically improved, and thus lithography resolution is inherently improved.

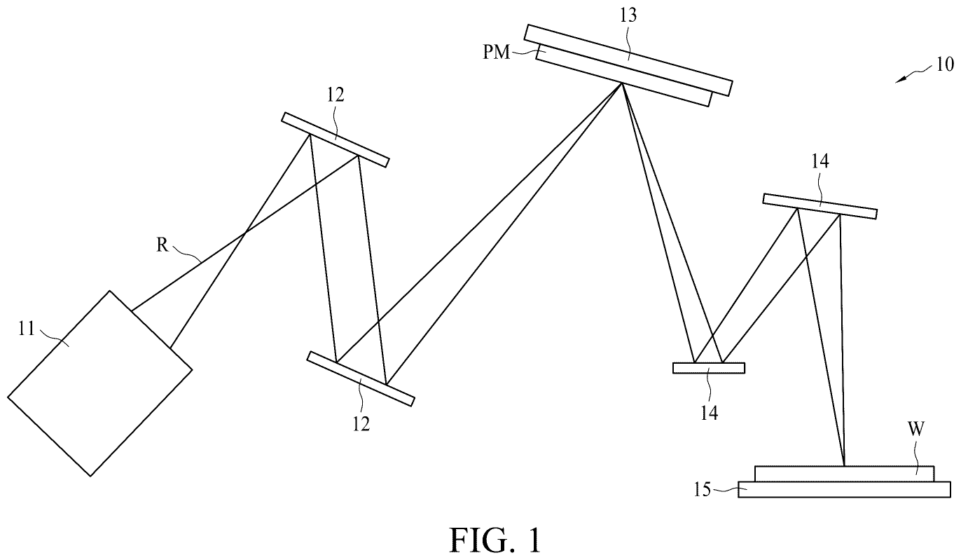

Please refer to FIG. 1, wherein FIG. 1 is a schematic view of an EUV lithography system 10 according to aspects of the present disclosure. The EUV lithography system 10 may be referred to as a scanner that is operable to perform lithographic processes. In some embodiments, the lithography processes are performed using EUV radiation R. In some embodiments, the EUV lithography system 10 includes an EUV light source module or a deep UV (DUV) light source module. For example, the EUV light source module may have a wavelength between about 1 nm and about 100 nm, and particularly, about 13.5 nm. In some embodiments, the DUV light source module may include a KrF excimer laser (e.g., to provide a 248 nm light source), an ArF excimer laser (e.g., to provide a 193 nm light source), or an F2 excimer laser (e.g., to provide a 157 nm light source).

In some embodiments, the EUV lithography system 10 includes a plurality of subsystems such as a light source 11, an illuminator 12, a mask stage 13, projection optics 14, and a substrate stage 15. A general description of the operation of the EUV lithography system 10 is given as follows: the EUV radiation R is emitted from the light source 11 and directed to the illuminator 12, and the EUV radiation R is projected onto an EUV photomask PM secured on the mask stage 13. In some embodiments, the illuminator 12 includes a set of reflective mirrors. A reflected mask image is directed to the projection optics 14, and the projection optics 14 focus and project the EUV radiation R onto a wafer W secured on the substrate stage 15, thereby exposing an EUV photoresist layer deposited on the wafer W. Additionally, in some embodiments, the EUV lithography system 10 may be housed in, and thus operate within, a high-vacuum environment, for example, to reduce atmospheric absorption of the EUV radiation R.

In some embodiments, the light source 11 may include a plasma source such as, for example but not limited thereto, a discharge produced plasma (DDP) or a laser produced plasma (LLD). In some embodiments, the light source 11 may include a collector, which may be used to collect the EUV radiation R generated from the plasma source and to direct the EUV radiation R toward the illuminator 12.

In some embodiments, the illuminator 12 includes reflective optics, such as a single mirror system having multiple mirrors in order to direct the EUV radiation R from the light source 11 toward the mask stage 13. In some embodiments, the illuminator 12 may include a zone plate, to improve focus of the EUV radiation R, but the disclosure is not limited thereto. In some embodiments, the illuminator 12 may shape the EUV radiation R passing therethrough in accordance with a pupil shape of, for example but not limited thereto, a dipole shape, a quadrapole shape, an annular shape, a single beam shape, a multiple beam shape, and/or a combination thereof. In some embodiments, the illuminator 12 is operable to configure the reflective elements such as the mirrors to provide a desired illumination to the EUV photomask PM. For example, the reflective elements such as the mirrors are modified or adjusted to reflect the EUV radiation R in different illumination directions. In some embodiments, other configurable mirrors may be used to direct the EUV radiation R in different illumination directions. In some embodiments, the illuminator 12 provides an on-axis illumination (ONI) to the EUV photomask PM. In some embodiments, the illuminator 12 provides an off-axis illumination (OAI) to the EUV photomask PM. In some embodiments, the optics employed in the illuminators 12 may include mirrors having multilayer thin-film coatings such as alternating layers of Mo and Si, which provide high reflectivity at EUV wavelengths.

In some embodiments, the mask stage 13 secures the EUV photomask PM. As mentioned above, the EUV lithography system 10 may be housed in, and thus operated within, a high-vacuum environment, and in some embodiments, the mask stage 13 includes an electrostatic chuck (e-chuck) to secure the EUV photomask PM.

As mentioned above, the EUV radiation R is reflected from the EUV photomask PM and directed toward the projection optics 14. The protection optics 14 collect the EUV radiation R reflected from the EUV photomask PM. In some embodiments, the EUV radiation R collected by the projection optics 14 carries an image of a pattern defined by the EUV photomask PM. In some embodiments, the projection optics 14 focus the collected EUV radiation R and project the EUV radiation R onto the wafer W to expose a photoresist layer deposited on the wafer W. In some embodiments, the projection optics 14 may include reflective optics. In some embodiments, the illuminator 12 and the projection optics 14 are collectively referred to as an optical module of the EUV lithography system 10.

The substrate stage 15 secures the wafer W to be patterned. In some embodiments, the wafer W includes a semiconductor wafer such as a silicon wafer, a germanium wafer, a silicon-germanium wafer, a III-V wafer, or another type of wafer as known in the art. Further, the wafer W may be coated with a resist layer that is sensitive to the EUV radiation R.

In some embodiments, the various subsystems of the EUV lithography system 10, including those described above, are integrated and are operable to perform lithography exposure processes including EUV lithography processes. The EUV lithography system 10 is exemplary only, and may further include other modules or subsystems which may be integrated with (or coupled to) one or more of the subsystems or components described herein. Additionally, the schematic representation of the EUV lithography system 10 is exemplary only and other configurations of lithography systems, now known or later developed, are equally applicable to aspects of the present disclosure.

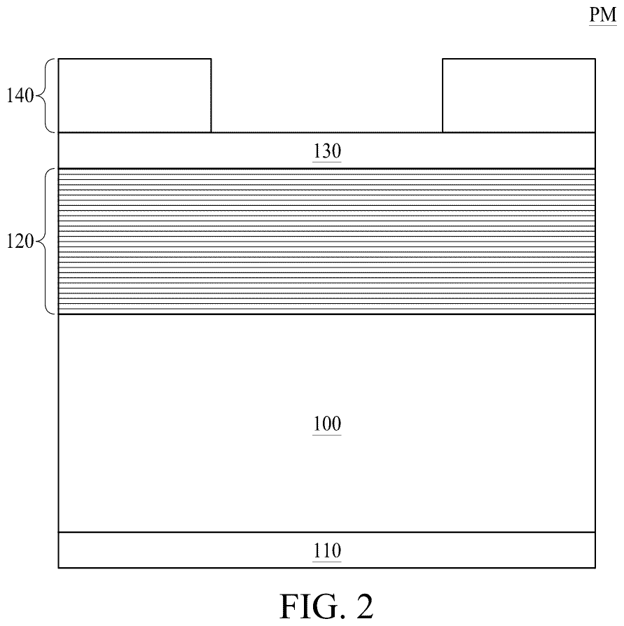

In the disclosure, the terms mask, photomask, and reticle may be used to refer to a same item. In some embodiments, the EUV photomask PM includes an APSM, but the disclosure is not limited thereto. Referring to FIG. 2. FIG. 2 is a cross-sectional view of an EUV photomask (i.e., the APSM) according to aspects of the present disclosure. The EUV photomask PM may include a substrate 100 having a backside coating layer 110, a multi-layer structure 120, a capping layer 130, and one or more absorber layers 140. The EUV photomask PM is exemplary only and may take other forms in other embodiments that may also benefit from aspects of the present disclosure including those with respect to embodiments of that include pellicles.

In some embodiments, the substrate 100 of the EUV photomask PM includes glass, silicon, quartz, or other low thermal expansion materials (LTEM). The low thermal expansion material helps to minimize image distortion due to mask heating during an exposure process of the EUV lithography operation. In some embodiments, the substrate 100 includes fused silica, fused quartz, calcium fluoride, silicon carbide, black diamond, or titanium oxide doped silicon oxide (TiO₂-doped SiO₂).

In some embodiments, the backside coating layer 110 provides for electrostatic coupling of the EUV photomask PM to an electrostatic mask chuck (not shown) during fabrication and use of the EUV photomask PM. In some embodiments, the backside coating layer 110 includes chromium nitride (CrN) or tantalum boride (TaB), but the disclosure is not limited thereto. In some embodiments, a thickness of the backside coating layer 110 is controlled such that the backside coating layer 110 is optically transparent.

Referring to FIG. 2, in some embodiments, the multi-layer structure 120 includes an alternately arranged molybdenum-silicon (Mo—Si) multi-layer structure. A Mo layer and a Si layer may be deposited over the substrate 100 using an ion deposition technique, but the disclosure is not limited thereto. A thickness of the multi-layer structure 120 may be between approximately 250 nm and approximately 350 nm. In such embodiments, each Mo—Si pair may have a thickness of about 3 nm for the Mo layer and about 4 nm for the Si layer. In some embodiments, a quantity of the Mo—Si pairs may be about 40, but the disclosure is not limited thereto. The thickness and/or the quantity of the Mo—Si pairs may be determined based in part on desired diffraction characteristics.

The capping layer 130 includes a material that resists oxidation and corrosion, and has a low chemical reactivity with common atmospheric gases such as oxygen, nitrogen and water vapor. In some embodiments, the capping layer 130 includes a transition metal such as ruthenium (Ru), iridium (Ir), rhodium (Rh), platinum (Pt), palladium (Pd), osmium (Os), rhenium (Re), vanadium (V), tantalum (Ta), hafnium (Hf), tungsten (W), zirconium (Zr), manganese (Mn), technetium (Te), molybdenum (Mo), or alloys thereof. In some embodiments, a thickness of the capping layer 130 may be between approximately 3 nm and 5 nm, but the disclosure is not limited thereto.

The absorber layer 140 over the capping layer 130 is used to absorb the EUV radiation R. In some embodiments, the absorber layer 140 include materials that satisfy two criteria: (1) there is a phase shift between approximately 1.1π and approximately 1.3π between a reflected EUV radiation from the absorber layer 140 and a reflected EUV radiation from the capping layer 130; and (2) there is a ratio of an EUV reflectivity of the absorber layer 140 over an EUV reflectivity of the capping layer 130 between approximately 4% and approximately 9% from a surface of the absorber layer 140. For example, the phase shift between the reflected EUV radiation from the absorber layer 140 and the reflected EUV radiation from the capping layer 130 may be 1.2π. In some embodiments, the absorber layer 140 includes an alloy made of two materials. In other embodiments, the absorber layer 140 includes a bi-layer structure including two material layers. In still other embodiments, absorber layer 140 a multi-layer structure including two material layers alternately stacked. Each of the alloy, the bi-layer structure and the multi-layer structure has a composition and a thickness that meet the abovementioned two criteria. Additionally, doping such as, for example but not limited thereto, oxygen (O) doping and/or nitrogen (N) doping may be used to tune optical constants of the absorber layer 140.

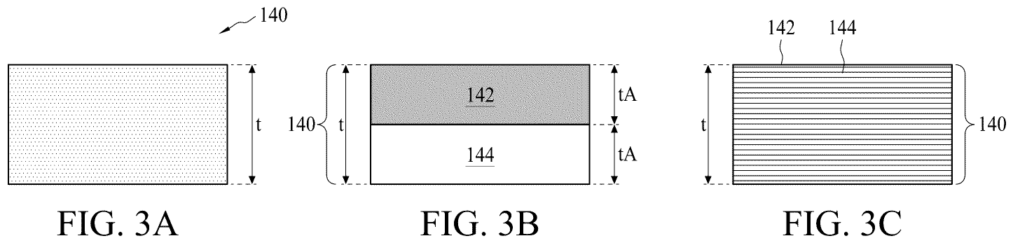

In some embodiments, when a wavelength of the EUV radiation R is approximately 13.5 nm, the EUV light source 11 has a p-polarization state, and an incident angle formed by the EUV radiation R and a mask normal line is approximately 6 degrees, various absorber layers 140 may be provided to meet the abovementioned two criteria. For example, when the capping layer 130 includes a Ru capping layer having a thickness of approximately 3.5 nm, a refractive index (n) of the absorber layer 140 is between approximately 0.860 and approximately 0.945, an extinction coefficient (k) of the absorber layer 140 is between approximately 0.070 and approximately 0.015, and a thickness (t, shown in FIGS. 3A to 3C) of the absorber layer 140 is between approximately 30 nm and approximately 65 nm. Accordingly, a reflected light from the capping layer 130 and a reflected light from the absorber layer 140 has a 1.2π phase shift, and the reflectivity ratio is between approximately 4% and approximately 9%.

In other embodiments, when the capping layer 130 includes a Ru/Rh capping layer having a thickness of approximately 1 nm of Ru and a thickness of approximately 1.5 nm of Rh, a refractive index of the absorber layer 140 is between approximately 0.855 and approximately 0.945, an extinction coefficient of the absorber layer 140 is between approximately 0.070 and approximately 0.015, and a thickness (t, shown in FIGS. 3A to 3C) of the absorber layer 140 is between approximately 30 nm and approximately 65 nm. Accordingly, a reflected light from the capping layer 130 and a reflected light from the absorber layer 140 have a 1.2π phase shift, and the reflectivity ratio is between approximately 4% and approximately 9%.

Please refer to FIGS. 3A to 3C, which are schematic cross-sectional views of the absorber layer 140 of various embodiments according to aspects of the present disclosure. Referring to FIG. 3A, in some embodiments, the absorber layer 140 includes an alloy of two elements. In such embodiments, the absorber layer 140 may be formed by physical vapor deposition (PVD), and the two elements are homogeneously mixed together to form a single alloy absorber layer 140. A ratio of the first material to the second material may be modified depending on different product designs. Additionally, in such embodiments, the material may be doped with oxygen and/or nitrogen to tune the optical constant of the absorber layer 140. For example, the absorber layer 140 may be doped with nitrogen and/or oxygen to increase the extinction coefficient.

Referring to FIG. 3B, the absorber layer 140 may be a bi-layer structure. For example, the absorber layer 140 may include a first layer 142 and a second layer 144 under the first layer 142. The first layer 142 and the second layer 144 include different materials, which are detailed below. In some embodiments, a thickness of the first layer 142 and a thickness of the second layer 144 may be equal. In some alternative embodiments, the thickness of the first layer 142 and the thickness of the second layer 144 may be different from each other. In some embodiments, the thickness of the first layer 142 and the thickness of the second layer 144 may be individually adjusted to obtain an optimized optical performance.

Referring to FIG. 3C, in some embodiments, the absorber layer 140 includes a multi-layer structure. For example, the absorber layer 140 includes a first layer 142 and a second layer 144 alternately stacked. The first layers 142 and the second layers 144 include different materials. In some embodiments, a thickness of each first layer 142 may be between approximately 0.1 nm and approximately 1.9 nm, and a thickness of each second layer 144 may be between approximately 0.1 nm and approximately 1.9 nm, but the disclosure is not limited thereto. In such embodiments, the thicknesses of the first layers 142 and the thicknesses of the second layers 144 are modified within the abovementioned ranges for equivalent etching. The thicknesses of the first layers 142 and the thicknesses of the second layers 144 may be equal. In some alternative embodiments, the thicknesses of the first layers 142 and the thicknesses of the second layers 144 may be different from each other. In some embodiments, the thicknesses of the first layers 142 and the thicknesses of the second layers 144 may be individually adjusted to obtain an optimized optical performance.

Still referring to FIGS. 3A to 3C, as mentioned above, the absorber layer 140 includes two materials (e.g., an alloy of two materials, a bi-layer structure with two materials layers, or a multi-layer with two material layers) hence the absorber layer 140 is referred to as a binary system.

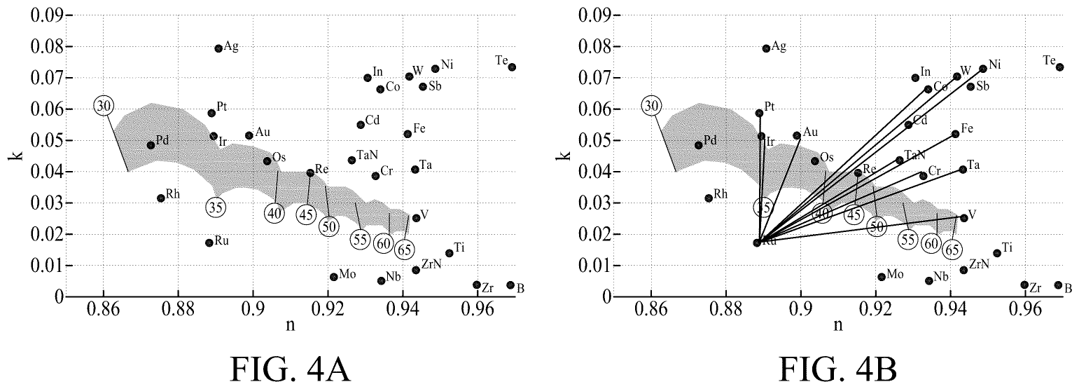

The binary system is constructed by operations given as follows: Referring to FIG. 4A, the refractive index and the extinction coefficient of each element can be depicted as dots and a potential thickness of the absorber layer 140 that satisfy the two criteria (i.e., 1.2π phase shift and the reflectivity ratio between approximately 4% and approximately 9%) may be depicted as an irregular frame. In some embodiments, two potential elements are chosen to form the binary system absorber layer 140. For example, ruthenium (Ru) and vanadium (V) are chosen, and a tie line is drawn to connect Ru and V. As shown in FIG. 4B, the Ru—V tie line in the irregular frame depicts a thickness range of the Ru—V absorber layer 140 of approximately 55 nm to approximately 65 nm. In such thickness range, the refractive index of the Ru—V absorber layer 140 is between 0.925 and 0.945, and the extinction coefficient of the Ru—V absorber layer 140 is between 0.015 and 0.030. In other embodiments, the two potential materials chosen to form the binary system absorber layer 140 are Ru and Ta, thus, a tie line is drawn to connect Ru and Ta. As shown in FIG. 4B, the Ru—Ta tie line in the irregular frame depicts a thickness range of the Ru—Ta absorber layer 140 of approximately 40 nm to approximately 55 nm. In such thickness range, the refractive index of the Ru—Ta absorber layer 140 is between 0.905 and 0.930, and the extinction coefficient of the Ru—Ta absorber layer 140 is between 0.025 and 0.035. Similar operations can be performed to form a Ru-based absorber layer 140. The thickness of the Ru-based absorber layer 140, the refractive index (n) of the Ru-based absorber layer 140 and the extinction coefficient (k) of the Ru-based absorber layer 140 are shown in Table 1:

TABLE 1

| Binary system | Thickness (nm) | n | k |
|---|---|---|---|
| Ru—V | 55-65 | 0.925-0.945 | 0.015-0.030 |
| Ru—Ta | 40-55 | 0.905-0.930 | 0.025-0.035 |
| Ru—Cr | 40-55 | 0.910-0.930 | 0.025-0.040 |
| Ru—Fe | 40-50 | 0.905-0.925 | 0.025-0.040 |
| Ru—TaN | 40-50 | 0.905-0.920 | 0.025-0.040 |
| Ru—Ni | 38-45 | 0.905-0.915 | 0.030-0.045 |
| Ru—W | 38-45 | 0.900-0.915 | 0.030-0.045 |
| Ru—Co | 38-45 | 0.900-0.915 | 0.030-0.045 |
| Ru—Au | 35-40 | 0.890-0.905 | 0.030-0.050 |
| Ru—Ir | 33-38 | 0.885-0.895 | 0.025-0.055 |
| Ru—Pt | 33-38 | 0.885-0.895 | 0.025-0.055 |

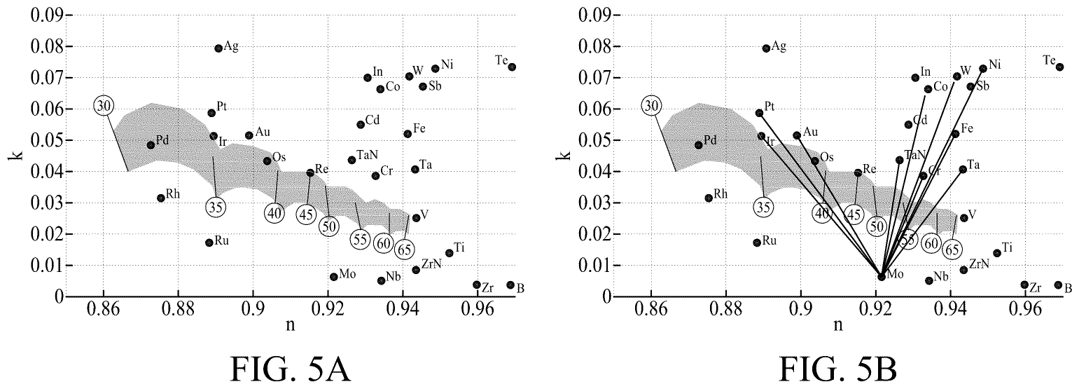

In some embodiments, the binary system can be constructed of other materials, such as molybdenum (Mo) and other elements. Operations for forming the Mo-based binary absorber layer 140 may be as follows: Referring to FIG. 5A, in some embodiments, two potential materials are chosen to form the binary system absorber layer 140. For example, Mo and Ta are chosen, and a tie line is drawn to connect Mo and Ta. As shown in FIG. 5B, the Mo—Ta tie line in the irregular frame depicts a thickness range of the Mo—Ta absorber layer 140 of approximately 55 nm to approximately 60 nm. In such thickness range, the refractive index of the Mo—Ta absorber layer 140 is between 0.930 and 0.940, and the extinction coefficient of the Mo—Ta absorber layer 140 is between 0.020 and 0.030. In other embodiments, the two potential materials chosen to form the binary system absorber layer 140 are Mo and Fe; thus, a tie line is drawn to connect Mo and Fe. As shown in FIG. 5B, the Mo—Fe tie line in the irregular frame depicts a thickness range of the Mo—Fe absorber layer 140 of approximately 52 nm to approximately 58 nm. In such thickness range, the refractive index of the Mo—Fe absorber layer 140 is between 0.925 and 0.935, and the extinction coefficient of the Mo—Fe absorber layer 140 is between 0.020 and 0.035. Similar operations can be performed to form the Mo-based absorber layer 140. The thickness of the Mo-based absorber layer 140, the refractive index (n) of the Mo-based absorber layer 140 and the extinction coefficient (k) of the Mo-based absorber layer 140 are shown in Table 2:

TABLE 2

| Binary system | Thickness (nm) | n | k |
|---|---|---|---|
| Mo—Ta | 55-60 | 0.930-0.940 | 0.020-0.030 |
| Mo—Fe | 52-58 | 0.925-0.935 | 0.020-0.035 |
| Mo—Ni | 52-58 | 0.925-0.935 | 0.020-0.035 |
| Mo—Cr | 52-58 | 0.925-0.935 | 0.020-0.035 |
| Mo—W | 52-58 | 0.925-0.935 | 0.020-0.035 |
| Mo—Co | 50-55 | 0.920-0.930 | 0.025-0.035 |
| Mo—TaN | 50-55 | 0.920-0.930 | 0.025-0.035 |
| Mo—Au | 35-45 | 0.895-0.915 | 0.025-0.050 |
| Mo—Pt | 35-42 | 0.890-0.910 | 0.025-0.050 |
| Mo—Ir | 33-40 | 0.885-0.910 | 0.025-0.050 |

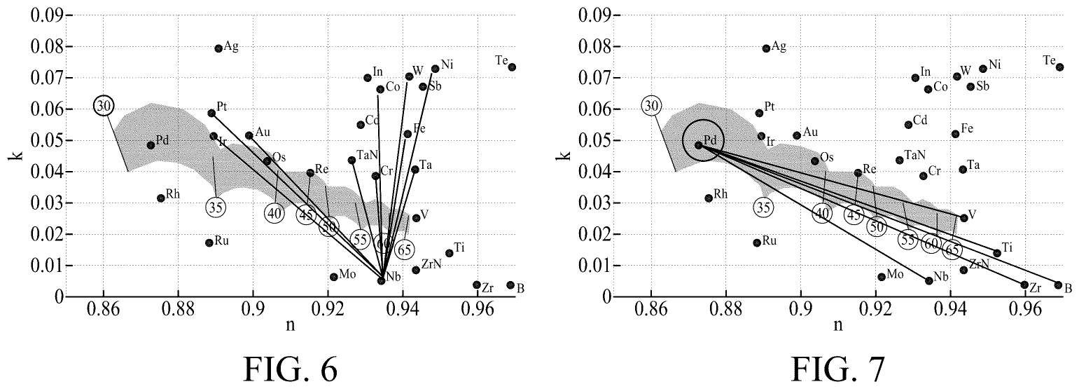

In some embodiments, the binary system can be constructed of other materials, such as niobium (Nb) and other elements. Operations for forming the Nb-based binary absorber layer 140 may be as follows: Referring to FIG. 6, two potential materials are chosen to form the binary system absorber layer 140. For example, Nb and Ta are chosen, and a tie line is drawn to connect Nb and Ta. As shown in FIG. 6, the Nb—Ta tie line in the irregular frame depicts a thickness range of the Nb—Ta absorber layer 140 of approximately 55 nm to approximately 65 nm. In such thickness range, the refractive index of the Nb—Ta absorber layer 140 is between 0.925 and 0.945, and the extinction coefficient of the Nb—Ta absorber layer 140 is between 0.020 and 0.035. Similar operations can be performed to form the Nb-based absorber layer 140. The thickness of the Nb-based absorber layer 140, the refractive index (n) of the Nb-based absorber layer 140 and the extinction coefficient (k) of the Nb-based absorber layer 140 are shown in Table 3:

TABLE 3

| Binary system | Thickness (nm) | n | k |
|---|---|---|---|
| Nb—Ta | 55-65 | 0.925-0.945 | 0.020-0.035 |
| Nb—Ni | 55-65 | 0.925-0.945 | 0.020-0.035 |
| Nb—Fe | 55-65 | 0.925-0.945 | 0.020-0.035 |
| Nb—W | 55-65 | 0.925-0.945 | 0.020-0.035 |
| Nb—Co | 55-65 | 0.925-0.945 | 0.020-0.035 |
| Nb—Cr | 55-65 | 0.925-0.945 | 0.020-0.035 |
| Nb—TaN | 55-65 | 0.925-0.945 | 0.020-0.035 |
| Nb—Au | 35-50 | 0.895-0.925 | 0.025-0.050 |
| Nb—Pt | 35-50 | 0.895-0.925 | 0.025-0.050 |
| Nb—Ir | 35-45 | 0.885-0.915 | 0.025-0.050 |

In some embodiments, the binary system can be constructed of other materials, such as palladium (Pd) and other elements. Operations for forming the Pd-based binary absorber layer 140 may be as follows: Referring to FIG. 7, two potential materials are chosen to form the binary system absorber layer 140. For example, Pd and V are chosen, and a tie line is drawn to connect Pd and V. As shown in FIG. 7, the Pd—V tie line in the irregular frame depicts a thickness range of the Pd—V absorber layer 140 of approximately 30 nm to approximately 65 nm. In such thickness range, the refractive index of the Pd—V absorber layer 140 is between 0.870 and 0.945, and the extinction coefficient of the PD-V absorber layer 140 is between 0.025 and 0.050. Similar operations can be performed to form the Pd-based absorber layer 140. The thickness of the Pd-based absorber layer 140, the refractive index (n) of the Pd-based absorber layer 140 and the extinction coefficient (k) of the Pd-based absorber layer 140 are shown in Table 4:

TABLE 4

| Binary system | Thickness (nm) | n | k |
|---|---|---|---|
| Pd—V | 30-65 | 0.870-0.945 | 0.025-0.050 |
| Pd—Ti | 30-60 | 0.870-0.945 | 0.020-0.050 |
| Pd—B | 30-60 | 0.870-0.940 | 0.015-0.050 |
| Pd—Zr | 30-55 | 0.870-0.935 | 0.020-0.050 |
| Pd—Nb | 30-40 | 0.870-0.905 | 0.030-0.050 |

In some embodiments, the Pd-based binary system provides a largest thickness range among all systems.

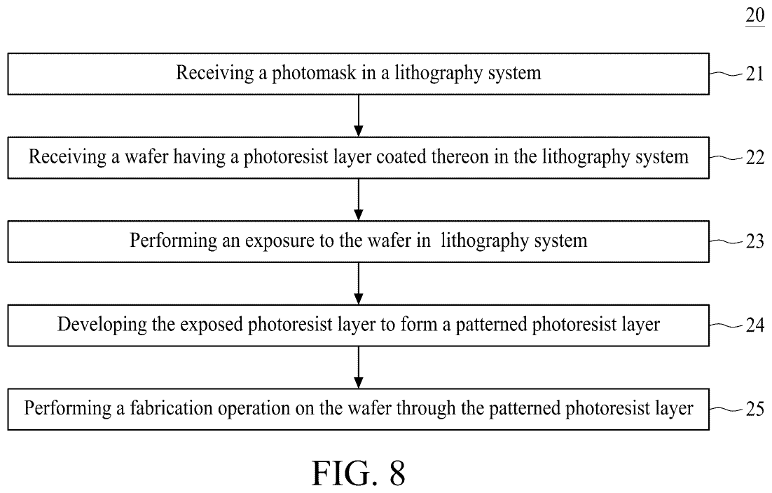

Referring to FIG. 2, accordingly, the EUV photomask PM including the binary system absorber layer 140 is provided for the EUV lithography operation. In some embodiments, the EUV photomask PM is used to fabricate a wafer. The fabrication of the wafer includes performing an EUV lithography process on the wafer using the EUV photomask PM. The fabrication may be further described as a method 20, as illustrated in FIG. 8.

FIG. 8 is a flowchart representing an EUV lithography method 20 according to aspects of the present disclosure. The method 20 includes a number of operations (21, 22, 23, 24 and 25). The method 20 will be further described according to one or more embodiments. It should be noted that additional processes may be provided before, during, and after the method 20, and that some other processes may be only briefly described herein. Thus, other implementations are possible within the scope of the various aspects described herein.

The method 20 may include an operation 21, in which a photomask is received in a lithography system. In some embodiments, the EUV photomask PM is received and loaded in the EUV lithography system 10, as shown in FIG. 1, that is operable to perform an EUV exposure operation. As mentioned above, the EUV photomask PM may be secured at the mask stage 13. The EUV photomask PM includes the abovementioned binary system absorber layer 140.

The method 20 may include an operation 22, in which a wafer is received in the lithography system. In some embodiments, the wafer W is received and loaded in the EUV lithography system 10, as shown in FIG. 1. As mentioned above, the wafer W may be secured at the wafer stage 15. In some embodiments, the wafer W may be coated with a photoresist layer which is sensitive the EUV radiation R.

The method 20 may further include an operation 23, in which an exposure operation is performed on the wafer in the EUV lithography system 10. The exposure operation uses the EUV photomask PM; therefore the mask pattern defined on the EUV photomask PM will be imaged on the photoresist layer coated on the wafer W. As mentioned above, the emitted EUV radiation R is projected to the EUV photomask PM through the illuminator 12.

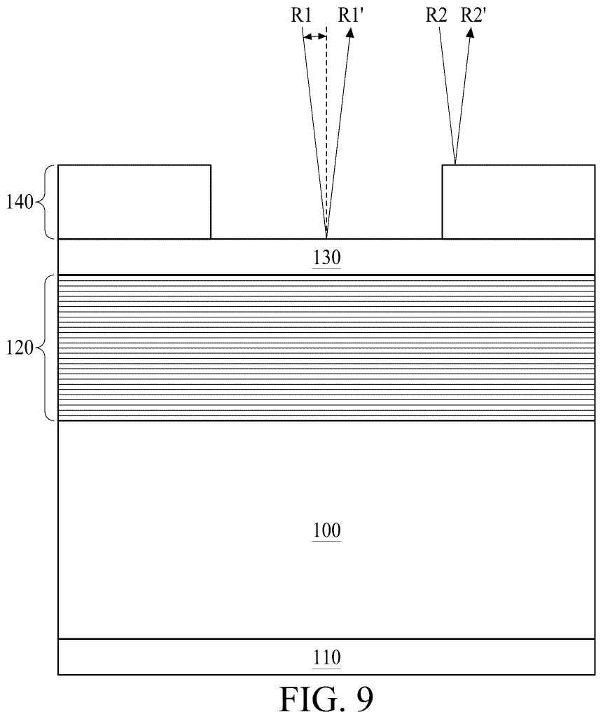

Referring to FIG. 9, in some embodiments, an incident EUV light R1 is emitted to the capping layer 130 and an incident EUV light R2 is emitted to the absorber layer 140. Wavelengths of the incident EUV lights R1 and R2 may be 13.5 nm and the light source 11 in a p-polarization state. An incident angle formed by the incident EUV light R1 and a normal of a surface of the capping layer 130 is 6 degrees, and an incident angle formed by the incident EUV light R2 and a normal of a surface of the absorber layer 140 is 6 degrees. As shown in FIG. 9, a reflected light R1′ is reflected from the capping layer 130, and a reflected light R2′ is reflected from the absorber layer 140. In some embodiments, due to the binary system of the absorber layer 140, the phase shift of the reflected light R1′ to the reflected light R2′ is 1.2π. Accordingly, a reflectivity ratio of the EUV radiation R (the reflected light R2′ over the reflected light R1′) is reduced to between approximately 4% and approximately 9%.

Referring back to FIG. 8, the method 20 may include an operation 24, in which the exposed photoresist layer is developed to form a patterned photoresist layer.

In some embodiments, the method 20 may further include an operation 25, in which a fabrication operation is performed on the wafer through the patterned photoresist layer. In some embodiments, the fabrication operation may be an etching operation that uses the patterned photoresist layer as an etching mask. In some embodiments, the patterned photoresist layer may be further used to pattern another mask layer in the etching operation. In some embodiments, the fabrication operation may be an ion implantation that uses the patterned photoresist layer as an implantation mask.

Accordingly, the present disclosure provides an APSM EUV photomask including a binary system absorber layer that provides high image contrast in a 0.33 NA scanner in an EUV lithography system. In some embodiments, NILS of the APSM photomask may be greater than 4, even when a thickness of the absorber layer is reduced to less than 60 nm in the 0.33 NA scanner. In some embodiments, the NILS of the APSM photomask may be still greater than 4 when the thickness of the absorber layer is between approximately 30 nm and approximately 50 nm. The thinner absorber layer is more suitable for an EUV lithography operation. Accordingly, instead of increasing an NA of an EUV scanner, a method of the present disclosure can easily and practically improve the image contrast, and thus a lithography resolution is inherently improved.

According to one embodiment of the present disclosure, an attenuated phase-shifting mask (APSM) is provided. The APSM includes a substrate, a multi-layer structure, a capping layer and an absorber layer. The substrate has a first side and a second side opposite to the first side. The multi-layer structure is disposed over the first side of the substrate. The capping layer is disposed over the multi-layer structure. The absorber layer is disposed over a portion of the capping layer. The absorber layer includes a first material and a second material different from the first material. A thickness of the absorber layer is between approximately 30 nm and approximately 65 nm. A refractive index (n) of the absorber layer is between approximately 0.860 and approximately 0.945. An extinction coefficient (k) of the absorber layer is between approximately 0.015 and approximately 0.070.

According to one embodiment of the present disclosure, an EUV lithography method is provided. The EUV lithography method includes following operations. A photomask is received on a mask stage of an EUV lithography system. A wafer is received on a wafer stage of the EUV lithography system. The photomask includes a substrate, a multi-layer structure over the substrate, a capping layer over the multi-layer structure, and an absorber layer over the capping layer. The absorber layer includes a first material and a second material different from the first material. An EUV light is emitted toward the photomask. The capping layer is illuminated by a first incident light, and the absorber layer is illuminated by a second incident light. A first reflected light is obtained from the capping layer, and a second reflected light is obtained from the absorber layer. The first reflected light and the second reflected light have a phase shift between approximately 1.1π and approximately 1.3π.

According to one embodiment of the present disclosure, an EUV lithography method is provided. The method includes following operations. A photomask is received on a mask stage of an EUV lithography system. The photomask includes a substrate, a multi-layer structure over the substrate, a capping layer over the multi-layer structure, and an absorber layer over the capping layer. The absorber layer includes a first material and a second material different from the first material. A wafer is received on a wafer stage of the EUV lithography system. A photoresist layer is coated on a surface of the wafer. An exposure is performed on the wafer in the lithography system. A reflected mask image is generated from the photomask and projected to the photoresist layer over the wafer. The exposed photoresist layer is developed to form a patterned photoresist layer. A fabrication operation is performed on the wafer through the patterned photoresist layer. A first reflected light is obtained from the capping layer and a second reflected light is obtained from the absorber layer 140 during the exposure, and the first reflected light and the second reflected light have a phase shift between approximately 1.1π and approximately 1.3π.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An attenuated phase-shifting mask (APSM) comprising:
a substrate having a first side and a second side opposite to the first side;
a multi-layer structure over the first side of the substrate;
a capping layer over the multi-layer structure; and
an absorber layer over a portion of the capping layer,
wherein the absorber layer comprises a first material and a second material different from the first material, a thickness of the absorber layer is between approximately 30 nm and approximately 65 nm, a refractive index (n) of the absorber layer is between approximately 0.860 and approximately 0.945, and an extinction coefficient (k) of the absorber layer is between approximately 0.015 and approximately 0.070.

2. The attenuated phase-shifting mask of claim 1, wherein the multi-layer structure comprises an alternately arranged molybdenum-silicon (Mo—Si) multi-layer structure.

3. The attenuated phase-shifting mask of claim 1, wherein the capping layer comprises ruthenium (Ru), iridium (Ir), rhodium (Rh), platinum (Pt), palladium (Pd), osmium (Os), rhenium (Re), vanadium (V), tantalum (Ta), hafnium (Hf), tungsten (W), zirconium (Zr), manganese (Mn), technetium (Te), molybdenum (Mo), or alloys thereof.

4. The attenuated phase-shifting mask of claim 1, wherein a thickness of the capping layer may be between approximately 3 nm and approximately 5 nm.

5. The attenuated phase-shifting mask of claim 1, further comprising a coating layer disposed over the second side of the substrate.

6. The attenuated phase-shifting mask of claim 5, wherein the coating layer comprises chromium nitride (CrN) or tantalum boride (TaB).

7. The attenuated phase-shifting mask of claim 1, wherein the absorber layer comprises an alloy, and the alloy comprises the first material and the second material.

8. The attenuated phase-shifting mask of claim 1, wherein the absorber layer comprises a bi-layer structure, the bi-layer structure comprises a first layer and a second layer, and the first layer comprises the first material and the second layer comprises the second material.

9. The attenuated phase-shifting mask of claim 1, wherein the absorber layer comprises a multi-layer structure, the multi-layer structure comprises a plurality of first layers and a plurality of second layers alternately stacked, and the first layers comprise the first material and the second layers comprise the second material.

10. The attenuated phase-shifting mask of claim 9, wherein the first material comprises ruthenium (Ru), molybdenum (Mo), niobium (Nb) or palladium (Pd).

11. The attenuated phase-shifting mask of claim 10, wherein the first material comprises Ru, and the second material comprises vanadium (V), tantalum (Ta), chromium (Cr), iron (Fe), tantalum nitride (TaN), nickel (Ni), tungsten (W), cobalt (Co), gold (Au), iridium (Ir), or platinum (Pt).

12. The attenuated phase-shifting mask of claim 10, wherein the first material comprises Mo, and the second material comprises Ta, Cr, Fe, TaN, Ni, W, Co, Au, Ir, or Pt.

13. The attenuated phase-shifting mask of claim 10, wherein the first material comprises Nb, and the second material comprises Ta, Cr, Fe, TaN, Ni, W, Co, Au, Ir, or Pt.

14. The attenuated phase-shifting mask of claim 10, wherein the first material comprises Pd, and the second material comprises V, titanium (Ti), boron (B), zirconium (Zr), or Nb.

15. The attenuated phase-shifting mask of claim 1, wherein the absorber layer comprises doped oxygen or doped nitrogen.

16. The attenuated phase-shifting mask of claim 1, wherein a ratio of an EUV reflectivity of the absorber layer over an EUV reflectivity of the capping layer is between approximately 4% and approximately 9%.

17. The attenuated phase-shifting mask of claim 1, wherein a reflected light from the capping layer and a reflected light from the absorber layer has a phase shift between approximately 1.1π and approximately 1.3π.

18. An EUV lithography method, comprising:
receiving a photomask and a wafer in an EUV lithography system, wherein the photomask comprises:
a substrate;
a multi-layer structure over the substrate;
a capping layer over the multi-layer structure; and
an absorber layer over the capping layer, wherein the absorber layer comprises a first material and a second material different from the first material;
emitting a first incident light and a second incident light to the photomask; and
obtaining a first reflected light from the capping layer and a second reflected light from the absorber layer,
wherein the first reflected light and the second reflected light have a phase shift between approximately 1.1π and approximately 1.3π.

19. An EUV lithography method, comprising:
receiving a photomask on a mask stage of an EUV lithography system, wherein the photomask comprises:
a substrate;
a multi-layer structure over the substrate;
a capping layer over the multi-layer structure; and
an absorber layer over the capping layer, wherein the absorber layer comprises a first material and a second material different from the first material;
receiving a wafer on a wafer stage of the EUV lithography system, wherein a photoresist layer is coated on a surface of the wafer;
performing an exposure on the wafer in the lithography system, wherein a reflected mask image is generated from the photomask and projected to the photoresist layer over the wafer;
developing the exposed photoresist layer to form a patterned photoresist layer; and
performing a fabrication operation on the wafer through the patterned photoresist layer,
wherein a first reflected light is obtained from the capping layer and a second reflected light is obtained from the absorber layer during the exposure, and the first reflected light and the second reflected light have a phase shift between proximately 1.1π and approximately 1.3π.

20. The method of claim 19, wherein a thickness of the absorber layer is between approximately 30 nm and approximately 65 nm.
